(19) United States
(12) Patent Application Publication
(10) Pub. No.: US 2021/0345493 A1
(43) Pub. Date: Nov. 4, 2021

(54) FLEXIBLE CIRCUIT BOARD, MANUFACTURING METHOD THEREFOR, AND PACKAGE HAVING FLEXIBLE CIRCUIT BOARD

(71) Applicant: STEMCO CO., LTD., Cheongju-si (KR)

(72) Inventors: Seong Jin LEE, Cheongju-si (KR); In Hwan SHIN, Cheongju-si (KR); Jin Gyu KIM, Cheongju-si (KR); Sang Won SHIN, Cheongju-si (KR)

(73) Assignee: STEMCO CO., LTD., Cheongju-si (KR)

(21) Appl. No.: 17/375,979

(22) Filed: Jul. 14, 2021

Related U.S. Application Data
(63) Continuation of application No. PCT/KR2020/000253, filed on Jan. 7, 2020.

(30) Foreign Application Priority Data
Jan. 14, 2019 (KR) 10-2019-0004404

(51) Int. Cl. H05K 1/18; H05K 3/28; H05K 1/02

(52) U.S. Cl. CPC H05K 1/189; H05K 1/0281; H05K 1/181; H05K 3/28

(57) ABSTRACT

Provided are a flexible circuit board for forming a protective layer on an inner lead region, a manufacturing method therefor, and a package having the flexible printed circuit board. The flexible circuit board comprises: a base layer; a wiring layer which includes a plurality of electrode lines each having an inner lead and an outer lead respectively provided on both sides thereof and which is formed on at least one surface of the base layer; a first protective layer formed on the wiring layer so as to expose the inner lead and the outer lead of the electrode line; and a second protective layer formed in an inner lead region that is formed by being encompassed by the first protective layer.

### CROSS-REFERENCE TO RELATED APPLICATIONS

This application is a Continuation of International Application No. PCT/KR2020/000253 filed Jan. 7, 2020, which claims benefit of priority to Korean Patent Application No. 10-2019-0004404 filed Jan. 14, 2019, the entire content of which is incorporated herein by reference.

### TECHNICAL FIELD

The present invention relates to a printed circuit board (PCB) and a method of manufacturing the same. More particularly, the present invention relates to a flexible printed circuit board (FPCB) and a method of manufacturing the same. Further, the present invention relates to a package having the flexible printed circuit board.

### BACKGROUND ART

A flexible printed circuit board (FPCB) refers to a circuit board having a copper foil, which is flexibly bent, coated on an insulating film. The flexible printed circuit board is thin and flexible unlike a rigid board and thus is suitable for reducing the weight of an electronic product.

The flexible printed circuit board includes an inner lead region, in which a semiconductor chip may be mounted, and an outer lead region, which is connected to an external device, on one surface thereof on which wires are formed.

### DISCLOSURE

### Technical Problem

When a semiconductor chip is mounted in an inner lead region of a flexible printed circuit board, a thermal compression process is performed to bond a bump 111 of a semiconductor chip 110 to an inner lead 120 of a wire.

However, in this case, as shown in FIG. 1, a phenomenon in which a base film 130 is bent due to thermal stress may occur, and accordingly, the base film 130 may come into contact with the semiconductor chip 110.

When the base film 130 comes into contact with the semiconductor chip 110, a thickness of a middle portion 140 of the inner lead region becomes less than a thickness of an outer periphery portion 150 of the inner lead region to reduce rigidity, and thus the semiconductor chip 110 may be damaged when a product is moved.

Meanwhile, according to a design change, conductive wires may be formed in the inner lead region. In this case, as the base film is bent, the conductive wires may come into contact with the semiconductor chip, and accordingly, an electrical failure such as a short circuit may occur.

An object of the present invention is to provide a flexible printed circuit board in which a protective layer is formed in an inner lead region, a method of manufacturing the same, and a package having the flexible printed circuit board.

It should be noted that objects of the present invention are not limited to the above-described object, and other objects of the present invention will be apparent to those skilled in the art from the following descriptions.

### Technical Solution

One aspect of the present invention provides a flexible printed circuit board including a base layer, a wiring layer including a plurality of electrode lines, each of which has an inner lead and an outer lead on both sides thereof, respectively, and formed on at least one surface of the base layer, a first protective layer formed on the wiring layer such that the inner lead and the outer lead of each of the electrode lines are exposed, and a second protective layer formed in an inner lead region that is formed to be surrounded by the first protective layer.

A height of the second protective layer may be less than or equal to a value obtained by summing a height of a bump of an electronic component mounted in the inner lead region and a height of the inner lead.

The wiring layer may further include an inner wire formed in the inner lead region separately from the electrode lines, and the second protective layer may be formed on the inner wire.

A height of the second protective layer may be less than or equal to a value obtained by subtracting a height of the inner wire from a value obtained by summing a height of a bump of an electronic component mounted in the inner lead region and a height of the inner lead.

The inner wire may be connected to an external wire through a metal layer filled in a via hole of the base layer, and the second protective layer may be formed to cover the metal layer.

The second protective layer may be formed to have a height of 3 μm to 50 μm.

The second protective layer may be formed to have an area of 1% to 50% of that of a mounting surface where a component is mounted.

The second protective layer may be formed in a portion of the inner lead region.

The second protective layer may be formed in a central portion of the inner lead region.

A plurality of second protective layers may be formed in the inner lead region.

Another aspect of the present invention provides a method of manufacturing a flexible printed circuit board, the method including forming a plurality of electrode lines, each of which has an inner lead and an outer lead on both sides thereof, respectively, on at least one surface of a base layer (S1), forming a first protective layer so as to cover the remaining portion of each of the electrode lines except for the inner lead and the outer lead (S2), and forming a second protective layer in an inner lead region formed to be surrounded by the first protective layer (S3).

The method may further include forming an inner wire, which is separately provided from the electrode lines, in the inner lead region (S4) between operations S1 and S2, wherein, in the forming of the second protective layer (S3), the second protective layer may be formed on the inner wire.

The method may further include forming a plating film on the electrode lines (S5), wherein, in the forming of the plating film (S5), the plating film may be formed on an entire surface of each of the electrode lines before the first protective layer is formed (between operations S1 and S2), or may be formed on the inner lead and the outer lead after the first protective layer is formed (between operations S2 and S3).

Still another aspect of the present invention provides a package including a flexible printed circuit board including a base layer, a wiring layer including a plurality of electrode lines, each of which has an inner lead and an outer lead on both sides thereof, respectively, and formed on at least one surface of the base layer, a first protective layer formed on the wiring layer such that the inner lead and the outer lead of each of the electrode lines are exposed, and a second protective layer formed in an inner lead region that is formed to be surrounded by the first protective layer, and an electronic component mounted in the inner lead region and electrically connected to the electrode lines through a bump.

Specific items of other embodiments are included in the detailed descriptions and drawings.

### Advantageous Effects

The present invention can obtain the following effects by including a protective layer in an inner lead region (a chip mounting region).

First, it is possible to prevent a substrate from coming into contact with a semiconductor chip and to prevent the semiconductor chip from being damaged by reinforcing the semiconductor chip.

Second, the reliability of a product can be secured.

### DESCRIPTION OF DRAWINGS

FIG. 1 is a cross-sectional view of a conventional flexible printed circuit board.

FIG. 2 is a plan view of a flexible printed circuit board according to one embodiment of the present invention.

FIG. 3 is a cross-sectional view of the flexible printed circuit board according to one embodiment of the present invention.

FIG. 4 is a plan view of a flexible printed circuit board according to another embodiment of the present invention.

FIG. 5 is a cross-sectional view of the flexible printed circuit board according to another embodiment of the present invention.

FIG. 6 is a cross-sectional view of a flexible printed circuit board according to still another embodiment of the present invention.

FIG. 7 is a flowchart schematically illustrating a method of manufacturing the flexible printed circuit board according to one embodiment of the present invention.

FIG. 8 is a flowchart illustrating a method of manufacturing the flexible printed circuit board according to another embodiment of the present invention.

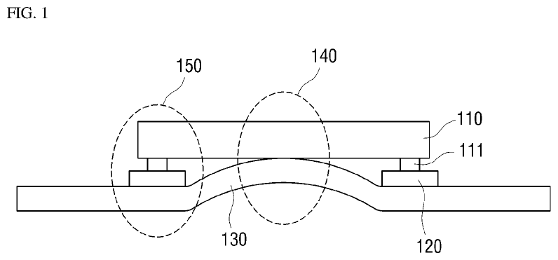

### MODES OF THE INVENTION

Hereinafter, exemplary embodiments of the present invention will be described in detail with reference to the accompanying drawings. Advantages and features of the present invention and methods for accomplishing the same will be more clearly understood from embodiments described below with reference to the accompanying drawings. However, the present invention is not limited to the embodiments disclosed below but may be implemented in various different forms. The embodiments are provided only to make the disclosure of the present invention complete, and to fully inform the scope of the invention to those skilled in the art to which the present invention pertains. The invention is only defined by the scope of the claims. Throughout the specification, like reference numerals refer to like elements.

When it is referred that an element or layer is “on” or “above” another element or layer, it includes a case where still another element or layer is interposed in the middle as well as directly above another element or layer. On the other hand, when it is referred that an element is “directly on” or “directly above” another element, it indicates that there is no intervening element or layer.

The spatially relative terms “below,” “beneath,” “lower,” “above,” “upper,” or the like may be used to easily describe the correlation between one element or component and another element or component as shown in the drawings. The spatially relative terms should be understood as terms including different directions of an element in use or operation in addition to the directions shown in the drawings. For example, if an element shown in the drawings is turned over, an element described as “below” or “beneath” of another element may be placed “above” another element. Accordingly, an exemplary term “below” may include both the directions below and above. An element may also be oriented in different directions, so that the spatially relative terms may be interpreted depending on the orientation.

Although the first, second, and the like are used to describe various elements, components, and/or sections, it goes without saying that these elements, components, and/or sections are not limited by these terms. These terms are only used to distinguish one element, component, or section from other elements, components, or sections. Accordingly, it goes without saying that a first element, a first component, or a first section described below may be a second element, a second component, or a second section within the technical spirit of the present invention.

The terms used herein are for the purpose of describing embodiments and are not intended to be limiting of the present invention. In the present specification, the singular also includes the plural unless specifically stated otherwise in the phrase. The terms “comprises” and/or “comprising” as used herein specify some stated components, steps, operations and/or elements, but do not exclude the presence or addition of one or more other components, steps, operations, and/or elements mentioned.

Unless otherwise defined, all terms (including technical and scientific terms) used herein may be used in a sense that may be commonly understood by those of ordinary skill in the art. In addition, the terms defined in the commonly used dictionaries are not ideally or excessively interpreted unless they are specifically defined clearly.

Hereinafter, embodiments of the present invention will be described in detail with reference to the accompanying drawings. In the description with reference to the accompanying drawings, the same or corresponding components are assigned the same reference numbers regardless of drawing numbers, and a redundant description thereof will be omitted.

Recently, a size of a bump of a semiconductor chip has been reduced in order to make the semiconductor chip light, thin, short, and small and to reduce material costs. Accordingly, a distance between a substrate and the semiconductor chip has become shorter than before, and thus, solving the problem that the substrate comes into contact with the semiconductor chip has become an important technical task.

The present invention relates to a flexible printed circuit board in which a protective layer is provided in an inner lead region (a chip mounting region). In the present invention, by providing the protective layer in the inner lead region, the substrate may be prevented from coming into contact with the semiconductor chip, and the reliability of a product may be secured.

Hereinafter, the present invention will be described in detail with reference to the drawings.

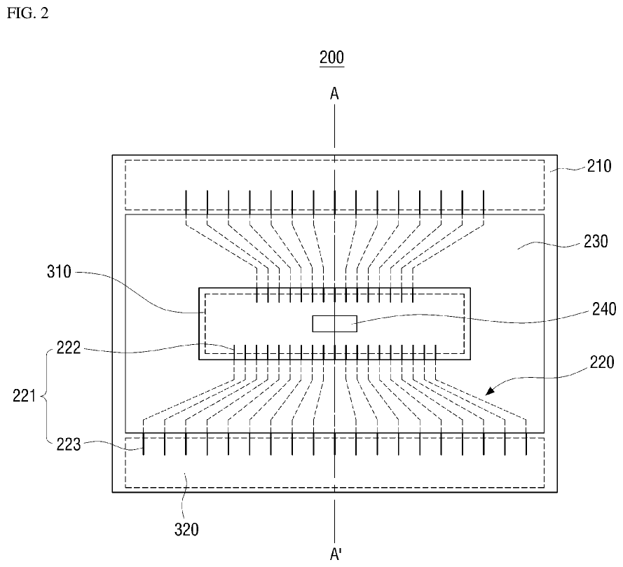

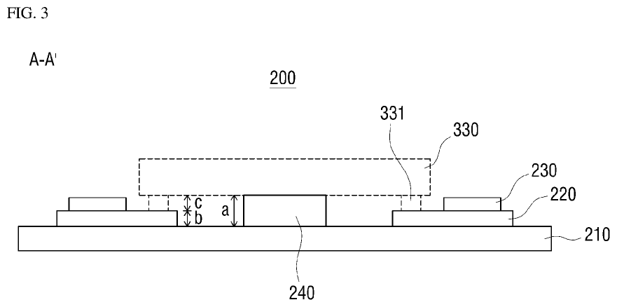

FIG. 2 is a plan view of a flexible printed circuit board according to one embodiment of the present invention, and FIG. 3 is a cross-sectional view of the flexible printed circuit board according to one embodiment of the present invention.

Referring to FIGS. 2 and 3, a flexible printed circuit board 200 according to one embodiment of the present invention may include a base layer 210, a wiring layer 220, a first protective layer 230, and a second protective layer 240.

The flexible printed circuit board 200 is a circuit board in which an electronic component such as a semiconductor chip 330 is mounted on one surface of the base layer 210 on which the wiring layer 220 is formed. The flexible printed circuit board 200 may be implemented as a chip on film (COF) package with the semiconductor chip 330 combined therein.

In the present embodiment, the flexible printed circuit board 200 includes the second protective layer 240 in an inner lead region 310 in which the semiconductor chip 330 is mounted. Through this, the flexible printed circuit board 200 may prevent the flexible printed circuit board 200 and the semiconductor chip 330 from coming into contact with each other, and may prevent damage to the semiconductor chip 330 by reinforcing the semiconductor chip 330.

The base layer 210 is a base film having a predetermined thickness (e.g., 5 μm to 100 μm).

The base layer 210 may be formed using at least one polymer material selected from among polymer materials including polyimide (PI), polyethylene terephthalate (PET), polyethylene naphthalate (PEN), polycarbonate, epoxy, glass fiber, and the like as a material thereof. As an example, the base layer 210 may be formed in the form of a polymer insulating film by using polyimide as a material thereof. However, the present embodiment is not limited thereto. The base layer 210 may also be formed using a polymer material other than the above-mentioned polymer material as a material thereof.

A seed layer (not shown) (or an under layer) may be formed on at least one surface of the base layer 210. The seed layer (or under layer) may be made of a conductive material to improve the adhesion between the base layer 210 and the wiring layer 220. As an example, the seed layer (or under layer) may be formed using at least one metal selected from among nickel (Ni), chromium (Cr), copper (Cu), and gold (Au) as a material thereof.

Meanwhile, the seed layer (or under layer) may be formed on the base layer 210 using a method such as a vacuum evaporation, adhesion, plating, or the like.

The wiring layer 220 serves as a wire that electrically connects the semiconductor chip 330 to an external device (not shown). The wiring layer 220 may be formed on at least one surface of the base layer 210 as a plurality of electrode lines 221.

The wiring layer 220 may be formed on the base layer 210 using at least one metal selected from among nickel (Ni), chromium (Cr), copper (Cu), gold (Au), silver (Ag), platinum (Pt), and the like as a material thereof.

The wiring layer 220 may be formed on the base layer 210 using an etching process. In this case, a metal layer is formed on the base layer 210 and wires are formed through photo etching, thereby forming the wiring layer 220 on the base layer 210.

The wiring layer 220 may also be formed on the base layer 210 using a plating process. In this case, a base metal layer is formed on the base layer 210, and then wires are formed through a semi-additive process, an additive process, printing, coating, or the like, thereby forming the wiring layer 220 on the base layer 210. In the above description, the semi-additive process refers to a process of forming a base metal layer on the base layer 210 and then removing the base metal layer other than wires. The additive process refers to a process of forming wires on the base layer 210 by plating, and the printing, the coating, or the like refers to a process of forming a metal paste or the like on the base layer 210 by printing, coating, or the like.

Each of the electrode lines 221 constituting the wiring layer 220 respectively includes an inner lead 222 and an outer lead 223 on both sides thereof. The electrode lines 221 may be formed to extend over the inner lead region 310, an outer lead region 320, and a redistribution region (not shown) that connects the inner lead 222 and the outer lead 223.

The inner lead 222 is a lead formed on one side of the electrode line 221 and is formed in the inner lead region 310.

The outer lead 223 is a lead formed on the other side of the electrode line 221, and is formed in the outer lead region 320.

The inner lead region 310 is a chip mounting region in which an electronic component such as the semiconductor chip 330 is mounted, and the outer lead region 320 is a region connected to an external electronic device. In addition, the redistribution region is a region formed between the inner lead region 310 and the outer lead region 320 and is a region in which the first protective layer 230 may be formed.

Meanwhile, a plating film (not shown) may be additionally formed on the wiring layer 220 using a metal such as tin, gold, or the like as a material thereof. The plating film is formed to improve the adhesion with a terminal of the electronic component and to prevent oxidation of copper wires.

The plating film may be formed to cover the entire wiring layer 220 before the first protective layer 230 is formed on the wiring layer 220. However, the present embodiment is not limited thereto. The plating film may also be formed to cover a portion of the wiring layer 220 exposed after the first protective layer 230 is formed.

The first protective layer 230 is formed to protect the wiring layer 220 exposed on the base layer 210. The first protective layer 230 is formed on the base layer 210 in the remaining region except for the inner lead region 310 and the outer lead region 320, that is, in the redistribution region. That is, the first protective layer 230 may be formed such that the inner lead 222 and the outer lead 223 of the electrode line are exposed, and may be formed to protect the remaining portion of the electrode line except for the inner lead 222 and the outer lead 223.

The first protective layer 230 may be formed using an insulating material as a material thereof. As an example, the first protective layer 230 may be formed using a solder resist as a material thereof.

The first protective layer 230 may be formed by printing or coating a liquid solder resist. However, the present embodiment is not limited thereto. The first protective layer 230 may also be formed by adhering a protective film (e.g., a coverlay film) onto the base layer 210 by a lamination method.

Meanwhile, the first protective layer 230 may be formed by applying a photosensitive material and then performing a photo-patterning process that exposes the inner lead region 310 and the outer lead region 320. In addition, the first protective layer 230 may also be formed by forming an insulating layer on the entire surface of the base layer 210 and then performing a photo processing method that removes a portion of the insulating layer. In the present embodiment, various materials or processing methods may be used to form the first protective layer 230 as long as an insulating layer capable of protecting the wiring layer 220 is formed.

The second protective layer 240 is formed in the inner lead region 310 to prevent the base layer 210 from directly coming into contact with the semiconductor chip 330 when the base layer 210 is bent. Like the first protective layer 230, the second protective layer 240 may be formed using an insulating material (e.g., a solder resist) as a material thereof.

Like the first protective layer 230, the second protective layer 240 may be formed by printing or coating a liquid solder resist, and may also be formed by adhering a coverlay film onto the inner lead region 310 by a lamination method. Here, the second protective layer 240 may be formed in the inner lead region 310 in the same manner as the first protective layer 230, but may also be formed on the inner lead region 310 in a different manner from the first protective layer 230.

The second protective layer 240 may be formed in a portion of the inner lead region 310. When the second protective layer 240 is formed in a portion of the inner lead region 310, the second protective layer 240 may be formed in a central portion of the inner lead region 310. However, the present embodiment is not limited thereto. The second protective layer 240 may also be selectively formed in a region that is likely to come into contact with a bottom surface of the semiconductor chip 330 according to design. Meanwhile, the second protective layer 240 may also be formed in the entire inner lead region 310.

In addition, the second protective layer 240 may be an insulating adhesive layer, and may adhesively fix the semiconductor chip 330 when the semiconductor chip 330 is mounted.

At least one second protective layer 240 may be formed in the inner lead region 310. In this case, the at least one second protective layer 240 may be formed at any position in the inner lead region 310 as long as the base layer 210 is prevented from directly coming into contact with the semiconductor chip 330.

The second protective layer 240 may be formed in a quadrangular shape in the inner lead region 310. However, the present embodiment is not limited thereto. The second protective layer 240 may be formed in various pattern shapes such as a polygonal shape such as a triangular shape and a pentagonal shape, a circular shape, and a stripe shape.

When a plurality of second protective layers 240 are formed in the inner lead region 310, the second protective layers 240 may be formed in the same shape. However, the present embodiment is not limited thereto. The second protective layers 240 may be formed in different shapes for each group, or may also be formed in different shapes.

The second protective layer 240 may be formed in the inner lead region 310 to have a predetermined height at which a connection between a bump 331 of the semiconductor chip 330 and the inner lead 222 is not interfered with. That is, when a height of the inner lead 222 is “b” and a height of the bump 331 of the semiconductor chip 330 is “c”, a height a of the second protective layer 240 may be formed to have a value (a<=b+c) less than or equal to a value obtained by summing of the height b of the inner lead 222 and the height c of the bump 331 of the semiconductor chip 330.

The second protective layer 240 should not interfere with the connection between the bump 331 of the semiconductor chip 330 and the inner lead 222, but on the other hand, the second protective layer 240 should prevent the base layer 210 from coming into contact with the semiconductor chip 330. Considering this aspect, the second protective layer 240 may be formed to have a height of 3 μm to 50 μm.

The second protective layer 240 may be formed in the inner lead region 310 to have a height sufficient to contact the bottom surface of the semiconductor chip 330. That is, the height a of the second protective layer 240 may be formed to be less than a value (b+c) obtained by summing the height b of the inner lead 222 and the height c of the bump 331 of the semiconductor chip 330 but close to the value (b+c). When the second protective layer 240 is formed as described above, the bending of the base layer 210 may be minimized when the semiconductor chip 330 is mounted in the inner lead region 310.

Meanwhile, an inner wire 224 may be formed in the inner lead region 310 according to a design change. In this case, the second protective layer 240 may be formed on the inner wire 224.

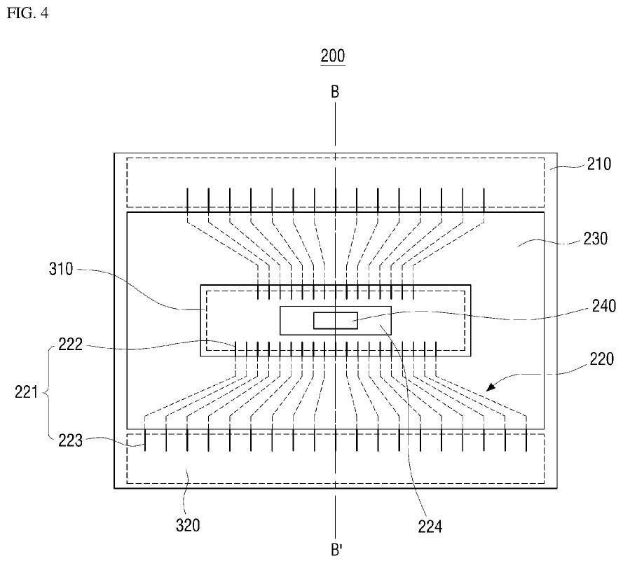

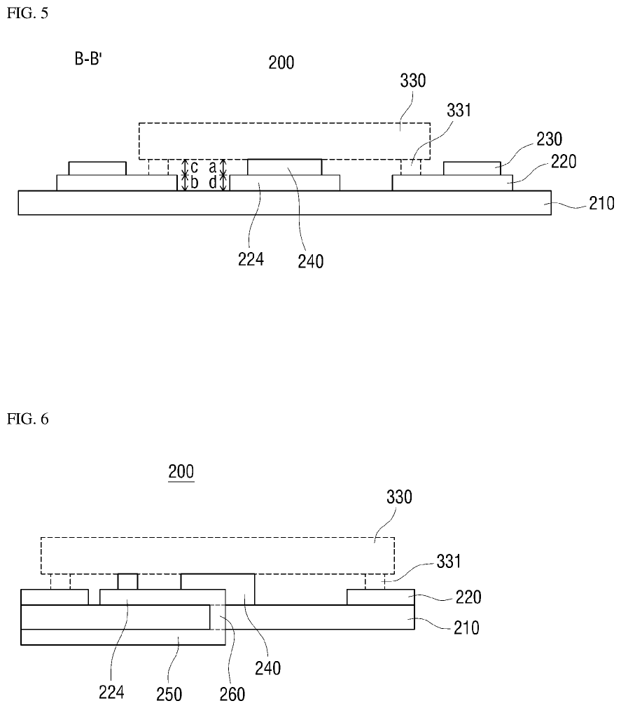

FIG. 4 is a plan view of a flexible printed circuit board according to another embodiment of the present invention, and FIG. 5 is a cross-sectional view of the flexible printed circuit board according to another embodiment of the present invention. Hereinafter, a description will be made with reference to FIGS. 4 and 5.

An inner wire 224 forms a wiring layer 220 together with an electrode line 221. The electrode line 221 is formed to extend from an inner lead region 310 to an outer lead region 320 to electrically connect a semiconductor chip 330 and an external device. On the other hand, according to a design change, the inner wire 224 is formed in the inner lead region 310 and is not connected to the electrode line 221.

A second protective layer 240 is formed on the inner wire 224. Through this, the second protective layer 240 may prevent the inner wire 224 and the semiconductor chip 330 from coming into contact with each other, thereby preventing an electrical failure (e.g., a short circuit) from occurring.

At least one second protective layer 240 may be formed on the inner wire 224. At this point, the second protective layer 240 may be formed to have a smaller area than the inner wire 224. However, the present embodiment is not limited thereto. The second protective layer 240 may also be formed to have the same area as the inner wire 224.

Meanwhile, the second protective layer 240 may also be formed on an upper surface and each side surface of the inner wire 224 so as to cover the inner wire 224.

The second protective layer 240 may be formed on the inner wire 224 to have a predetermined height at which a connection between a bump 331 of the semiconductor chip 330 and an inner lead 222 is not interfered with. That is, when a height of the inner wire 224 is “d”, a height a of the second protective layer 240 may be formed to have a value (a<=b+c−d) less than or equal to a value obtained by subtracting the height d of the inner wire 224 from a value obtained by summing a height b of the inner lead 222 and a height c of the bump 331 of the semiconductor chip 330.

As shown in FIG. 6, the inner wire 224 may also be connected to an external wire 250 formed on the other surface of a base layer 210 through a metal layer 260 formed in a via hole 211 of the base layer 210. In this case, the second protective layer 240 may be formed to cover the metal layer 260.

FIG. 6 is a cross-sectional view of a flexible printed circuit board according to still another embodiment of the present invention. Hereinafter, a description will be made with reference to FIG. 6.

A via hole 211 is filled with a metal layer 260 to electrically connect an inner wire 224 and an external wire 250. A second protective layer 240 is formed to cover the metal layer 260, thereby preventing the metal layer 260 from coming into contact with a semiconductor chip 330.

In the above embodiments, an area of the second protective layer 240 may be less than an area of a mounting surface on which bumps of the semiconductor chip 330 being mounted are formed and may be 1% to 50% of the area of the mounting surface. The second protective layer 240 may have an area capable of preventing the semiconductor chip 330 and the flexible printed circuit board from coming into contact with each other, and as an area in which the second protective layer 240 is formed becomes smaller, the more advantageous it is. When the area is beyond the above range, there may be a problem in that an applying amount is unnecessarily increased and thus material costs are increased.

Next, a method of manufacturing the flexible printed circuit board 200 will be described.

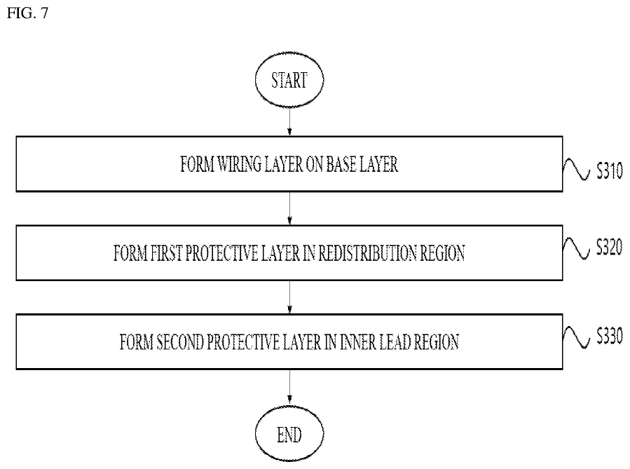

FIG. 7 is a flowchart schematically illustrating a method of manufacturing the flexible printed circuit board according to one embodiment of the present invention. Hereinafter, a description will be made with reference to FIGS. 2, 3, and 7.

First, a wiring layer 220 is formed on a base layer 210 (S310). At this point, a plurality of electrode lines 221 constituting the wiring layer 220 are formed to extend from an inner lead region 310 to an outer lead region 320 through a redistribution region.

Thereafter, in order to protect the electrode lines located in the redistribution region, a first protective layer 230 is formed on the electrode lines (S320). When the first protective layer 230 is formed, only an inner lead 222 and an outer lead 223 of each of the electrode lines 221 are exposed.

Thereafter, a second protective layer 240 is formed in the inner lead region 310 (S330). The second protective layer 240 may be formed after the first protective layer 230 is formed, but may also be formed simultaneously with the first protective layer 230.

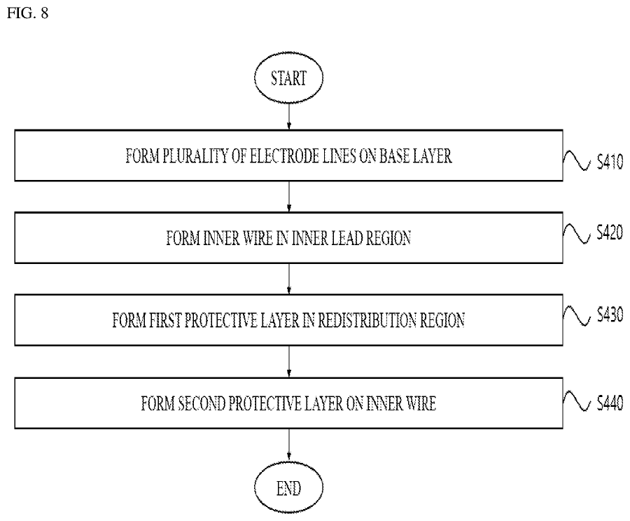

FIG. 8 is a flowchart illustrating a method of manufacturing the flexible printed circuit board according to another embodiment of the present invention. Hereinafter, a description will be made with reference to FIGS. 4, 5, and 8.

First, a plurality of electrode lines 221 constituting a wiring layer 220 are formed on a base layer 210 (S410).

Thereafter, an inner wire 224 constituting the wiring layer 220 is formed in an inner lead region 310 (S420). In the present embodiment, the inner wire 224 may be formed after the electrode lines 221 are formed, but the inner wire 224 may also be formed simultaneously with the electrode lines 221.

Thereafter, a first protective layer 230 is formed to protect the electrode lines in a redistribution region (S430).

Thereafter, a second protective layer 240 is formed on the inner wire 224 (S440). The second protective layer 240 may be formed after the first protective layer 230 is formed, but may also be formed simultaneously with the first protective layer 230.

While the embodiments of the present invention have been described with reference to the accompanying drawings, it should be understood by those skilled in the art that various modifications may be made without departing from the technical spirit of the present invention and without changing essential features thereof. Therefore, it should be understood that the above-described embodiments are not restrictive but illustrative in all aspects.

### INDUSTRIAL APPLICABILITY

The present invention may be applied to a circuit board.

1. A flexible printed circuit board comprising:
a base layer;
a wiring layer including a plurality of electrode lines, each of which has an inner lead and an outer lead on both sides thereof, respectively, and formed on at least one surface of the base layer;
a first protective layer formed on the wiring layer such that the inner lead and the outer lead of each of the electrode lines are exposed; and
a second protective layer formed in an inner lead region that is formed to be surrounded by the first protective layer.

2. The flexible printed circuit board of claim 1, wherein a height of the second protective layer is less than or equal to a value obtained by summing a height of a bump of an electronic component mounted in the inner lead region and a height of the inner lead.

3. The flexible printed circuit board of claim 1, wherein
the wiring layer further includes an inner wire formed in the inner lead region separately from the electrode lines, and
the second protective layer is formed on the inner wire.

4. The flexible printed circuit board of claim 3, wherein a height of the second protective layer is less than or equal to a value obtained by subtracting a height of the inner wire from a value obtained by summing a height of a bump of an electronic component mounted in the inner lead region and a height of the inner lead.

5. The flexible printed circuit board of claim 3, wherein
the inner wire is connected to an external wire through a metal layer filled in a via hole of the base layer, and
the second protective layer is formed to cover the metal layer.

6. The flexible printed circuit board of claim 1, wherein the second protective layer is formed to have a height of 3 μm to 50 μm.

7. The flexible printed circuit board of claim 1, wherein the second protective layer is formed to have an area of 1% to 50% of that of a mounting surface where a component is mounted.

8. The flexible printed circuit board of claim 1, wherein the second protective layer is formed in a portion of the inner lead region.

9. The flexible printed circuit board of claim 8, wherein the second protective layer is formed in a central portion of the inner lead region.

10. The flexible printed circuit board of claim 1, wherein a plurality of second protective layers are formed in the inner lead region.

11. A method of manufacturing a flexible printed circuit board, the method comprising:
forming a plurality of electrode lines, each of which has an inner lead and an outer lead on both sides thereof, respectively, on at least one surface of a base layer;
forming a first protective layer so as to cover the remaining portion of each of the electrode lines except for the inner lead and the outer lead; and
forming a second protective layer in an inner lead region formed to be surrounded by the first protective layer.

12. The method of claim 11, further comprising forming an inner wire, which is separately provided from the electrode lines, in the inner lead region,
wherein, in the forming of the second protective layer, the second protective layer is formed on the inner wire.

13. The method of claim 11, further comprising forming a plating film on the electrode lines,
wherein, in the forming of the plating film, the plating film is formed on an entire surface of each of the electrode lines before the first protective layer is formed, or is formed on the inner lead and the outer lead after the first protective layer is formed.

14. A package comprising:
a flexible printed circuit board including a base layer, a wiring layer including a plurality of electrode lines, each of which has an inner lead and an outer lead on both sides thereof, respectively, and formed on at least one surface of the base layer, a first protective layer formed on the wiring layer such that the inner lead and the outer lead of each of the electrode lines are exposed, and a second protective layer formed in an inner lead region that is formed to be surrounded by the first protective layer; and
an electronic component mounted in the inner lead region and electrically connected to the electrode lines through bumps.
